(19) United States
(12) Patent Application Publication
(10) Pub. No.: US 2026/0304712 A1
(43) Pub. Date: Oct. 1, 2026

(54) CONTROL APPARATUS FOR VEHICLE

(71) Applicant: HYUNDAI MOBIS CO., LTD., Seoul (KR)

(72) Inventor: Kyeong Jun LEE, Yongin-si (KR)

(73) Assignee: HYUNDAI MOBIS CO., LTD., Seoul (KR)

(21) Appl. No.: 19/386,419

(22) Filed: Nov. 12, 2025

(30) Foreign Application Priority Data
Mar. 28, 2025 (KR) 10-2025-0040425

(51) Int. Cl. H05K 7/20

(52) U.S. Cl. CPC H05K 7/20854; H05K 7/20409; H05K 7/20454; H05K 7/2049

(57) ABSTRACT

A control apparatus for vehicle, including: a lower housing having an accommodation space formed therein to accommodate a printed circuit board; a heating element coupled to the printed circuit board; a thermal paste layer formed on an upper surface of the heating element; and an upper housing including a heat sink portion on one surface, wherein the thermal paste layer is formed such that an upper surface thereof is in contact with at least a portion of the heat sink portion, wherein the heat sink portion includes: one or more plates; and a coupling portion formed such that a wrench engages therewith, and wherein at least one of the one or more plates has one end coupled to the coupling portion.

### CROSS-REFERENCE TO RELATED APPLICATION

The present application claims priority to Korean Patent Application No. 10-2025-0040425, filed on Mar. 28, 2025, the entire contents of which is incorporated herein for all purposes by this reference.

### TECHNICAL FIELD

The disclosure relates to a control apparatus for vehicle. More specifically, the disclosure relates to a control apparatus for vehicle capable of removing air bubbles formed inside a thermal paste.

### BACKGROUND ART

The content described in this section merely provides background information for the disclosure and does not constitute the related art.

The vehicle is equipped with a control apparatus for vehicle such as an ECU (electronic control unit), MCU (micro controller unit). The control apparatus for vehicle receives information from sensors, switches, or the like installed in respective parts of the vehicle, and processes the received information or performs control operations. The control apparatus for vehicle performs various control operations to improve the riding comfort and driving safety of the vehicle and to provide various conveniences to the driver and passengers.

The control apparatus for vehicle includes a housing and a PCB (printed circuit board) accommodated inside the housing, and the PCB includes electronic components. When the control apparatus for vehicle is operated, the electronic components generate heat, and the temperature of the control apparatus for vehicle increases. When the electronic components are overheated, the performance of the control apparatus for vehicle may be degraded.

In order to lower the temperature of the control apparatus for vehicle and prevent overheating of the electronic components, the control apparatus for vehicle may further include a heat sink structure. The heat sink is formed to absorb heat generated from the electronic components and to release the absorbed heat toward the outside of the control apparatus for vehicle. The larger the surface area of the heat sink, the easier it is to radiate heat toward the outside of the control apparatus for vehicle. The heat sink may further include a plate to increase the surface area. The electronic components and the heat sink are formed to be in contact with each other, so that heat generated from the electronic components may be transferred toward the heat sink.

When the electronic component has a non-uniform surface, an air layer or air bubbles may be formed between the electronic components and the heat sink. When an air layer or air bubbles are formed between the electronic components and the heat sink, there is a problem in that the heat transfer efficiency of the heat sink is degraded.

In order to easily transfer the heat generated from the electronic components towards the heat sink, the control apparatus for vehicle may further include a thermal paste. The thermal paste may be formed between the electronic components and the heat sink to transfer heat generated from the electronic components toward the heat sink. The thermal paste has a liquid phase, and a user may apply the thermal paste between the electronic components and the heat sink. When the thermal paste is applied, a thermal paste layer is formed. When the process of applying the thermal paste is performed, the air bubbles may be formed inside the thermal paste layer. When the air bubbles are formed inside the thermal paste layer, there is a problem in that the heat dissipation performance of the thermal paste layer is degraded.

The thermal paste layer may apply pressure toward the electronic components. The air bubbles increase the pressure applied by the thermal paste layer toward the electronic components. When the electronic components are subjected to excessive pressure, there is a problem in that the electronic components are damaged.

When the air bubbles formed inside the thermal paste layer are removed, the air bubbles may be removed by applying vibration to the heat sink. A vibrating device (not shown) and the heat sink are coupled, and the heat sink is vibrated to remove the air bubbles. However, when the process of applying vibration to the heat sink is performed, there may be a problem in that the plate is physically damaged.

### DISCLOSURE OF INVENTION

### Technical Problem

An aspect of the disclosure is to provide a control apparatus for vehicle including one or more plates in a heat sink portion.

According to an embodiment of the disclosure, an aspect of the disclosure is to provide a control apparatus for vehicle capable of removing air bubbles formed inside a thermal paste layer by applying vibration to a heat sink portion.

According to an embodiment of the disclosure, an aspect of the disclosure is to provide a control apparatus for vehicle formed to allow a wrench to engage therewith by including a coupling portion in a heat sink portion.

### Solution to Problem

According to an embodiment of the disclosure, there is provided a control apparatus for vehicle, including: a lower housing having an accommodation space formed therein to accommodate a printed circuit board; a heating element coupled to the printed circuit board; a thermal paste layer formed on an upper surface of the heating element; and an upper housing including a heat sink portion on one surface, wherein the thermal paste layer is formed such that an upper surface thereof is in contact with at least a portion of the heat sink portion, wherein the heat sink portion includes: one or more plates; and a coupling portion formed such that a wrench engages therewith, and wherein at least one of the one or more plates has one end coupled to the coupling portion.

According to an embodiment of the disclosure, there is provided a control apparatus for vehicle, including: a lower housing having an accommodation space formed therein to accommodate a printed circuit board; a heating element coupled to the printed circuit board; a thermal paste layer formed on an upper surface of the heating element; and an upper housing including a heat sink portion on one surface, wherein the thermal paste layer is formed such that an upper surface thereof is in contact with at least a portion of the heat sink portion, wherein the heat sink portion further comprises a radiation hole with a groove formation that allows a wrench to engage therewith, the radiation hole including a first radiation line to an m-th radiation line, and wherein the first radiation line to the m-th radiation line are formed to extend radially from a center of the radiation hole and are arranged to be spaced apart from each other so as to form a first plate to an m-th plate.

### Effects of Disclosure

According to an embodiment of the disclosure, an effect of increasing the surface area of the heat sink portion is provided by including one or more plates in the heat sink portion.

According to an embodiment of the disclosure, an effect of removing air bubbles formed inside a thermal paste layer is provided by applying vibration to the heat sink portion.

According to an embodiment of the disclosure, an effect of applying vibration without damaging the plates is provided by including, in the heat sink portion, a coupling portion to which a wrench is coupled.

### BRIEF DESCRIPTION OF DRAWINGS

FIG. 1 is an exploded perspective view of a control apparatus for vehicle according to an embodiment of the disclosure.

FIG. 2 is a perspective view of a control apparatus for vehicle according to an embodiment of the disclosure.

FIG. 3 is a cross-sectional view taken along line A-A′ of FIG. 1.

FIG. 4 is a plan view showing a first embodiment of a heat sink portion according to the disclosure.

FIG. 5 is a plan view showing a second embodiment of a heat sink portion according to the disclosure.

FIG. 6 is a plan view showing a third embodiment of a heat sink portion according to the disclosure.

FIG. 7 is a plan view showing a fourth embodiment of a heat sink portion according to the disclosure.

### DETAILED DESCRIPTION FOR CARRYING OUT THE INVENTION

Hereinafter, some embodiments of the disclosure will be described in detail with reference to illustrative drawings. It should be noted that, in adding reference numerals to the components in each drawing, the same reference numerals are used for the same components as much as possible, even if they are shown in different drawings. In addition, in describing the disclosure, when it is determined that a specific description of a related known configuration or function may obscure the gist of the disclosure, a detailed description thereof will be omitted.

In describing the components of the embodiments according to the disclosure, reference numerals such as first, second, i), ii), a), and b) may be used. These numerals are merely used to distinguish one component from another component, and do not limit the nature, order, sequence, or the like of that components by such numerals. In the specification, when a part is described as “comprising” or “including” a certain component, it means that other components may be further included instead of excluding other components unless explicitly stated to the contrary.

In describing the components of the disclosure, the terms such as first, second, A, B, (a), (b) may be used. These terms are merely used to distinguish one component from another component, and do not limit the nature, order, sequence, or the like of that components by the terms.

When a component is described as being “connected,” “coupled,” or “joined” to another component, it should be understood that the component may be directly connected or joined to the other component, but that another component may be “connected,” “coupled,” or “joined” between the components.

Unless described otherwise, it should be noted that the description of any one embodiment may be applied to other embodiments.

The description of the invention disclosed below in conjunction with the accompanying drawings is intended to describe exemplary embodiments of the disclosure and is not intended to represent the only embodiment in which the disclosure may be practiced.

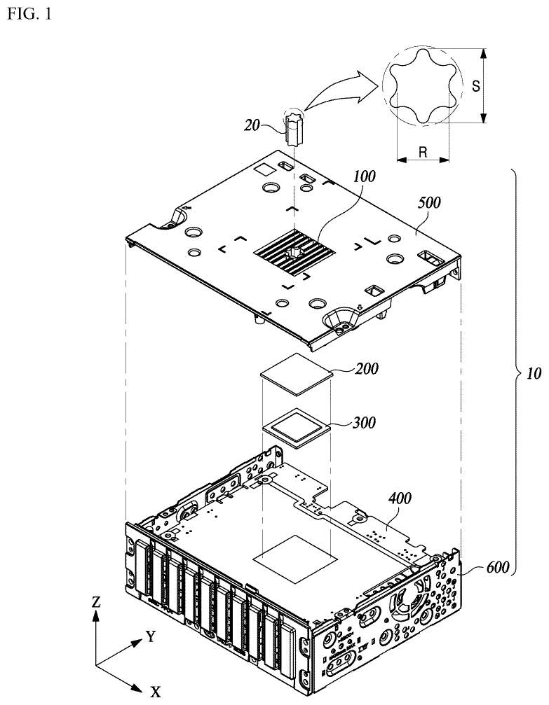

FIG. 1 is an exploded perspective view of a control apparatus for vehicle according to an embodiment of the disclosure.

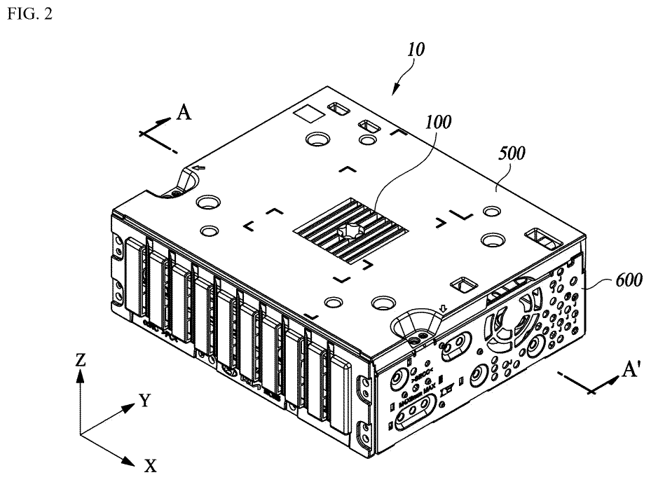

FIG. 2 is a perspective view of a control apparatus for vehicle according to an embodiment of the disclosure.

Referring to FIG. 1 and FIG. 2, the control apparatus for vehicle 10 includes a heat sink portion 100, a thermal paste layer 200, a heating element 300, a printed circuit board 400, and housings 500, 600. The heating element 300 is coupled to the printed circuit board 400, and the thermal paste layer 200 is formed on an upper surface of the heating element 300. The heat sink portion 100 is formed on an upper surface of the thermal paste layer 200.

The housings 500, 600 may have an accommodation space formed therein to accommodate the printed circuit board 400, and may further include an upper housing 500 and a lower housing 600. The printed circuit board 400 is accommodated inside the lower housing 600, and the upper housing 500 is formed to be coupled to the lower housing 600 to cover the printed circuit board 400.

The heating element 300 is coupled to the printed circuit board 400. The heating element 300 may include a microcontroller, a semiconductor element, a resistor, and a power supply element. The larger the amount of MCU (microcontroller unit) computation, the more heat it generates. A MOSFET (metal-oxide-semiconductor field-effect transistor) is an element included in a switching circuit, and when the MOSFET performs switching operations, it may consume a large amount of power and generate heat. When the power supply element performs a power conversion process, power loss may occur and heat may be generated.

According to an embodiment of the disclosure, the heat sink portion 100 is formed on one surface of the upper housing 500, and is formed to be in contact with the heating element 300. When the heating element 300 is formed adjacent to the lower housing 600, the heat sink portion 100 may be formed on one surface of the lower housing 600. Regardless of the position where the heating element 300 is formed, the heat sink portion 100 is formed so as to be in contact with the heating element 300, and dissipates heat generated from the heating element 300.

According to an embodiment of the disclosure, the heat sink portion 100 is formed to absorb heat transferred from the heating element 300 and to release the absorbed heat toward the outside of the control apparatus for vehicle 10. The heat sink portion 100 is formed to have high thermal conductivity by including a metal material. The higher the thermal conductivity of the heat sink portion 100, the faster it may radiate heat.

When the heating element 300 has a non-uniform surface, an air layer may be formed between the heating element 300 and the heat sink portion. When it is desired to use the control apparatus for vehicle 10 under conditions of room temperature (about 25° C.) and atmospheric pressure (about 1 atm), the thermal conductivity coefficient of air has a value of about 0.0257 W/m·K. The thermal conductivity coefficient of air is significantly lower than the thermal conductivity coefficient of copper (about 385 W/m·K), the thermal conductivity coefficient of aluminum (about 205 W/m·K) and the thermal conductivity coefficient of iron (about 80 W/m·K). When the air layer is formed between the heating element and the heat sink portion 100, the heat transfer efficiency may be reduced.

The control apparatus for vehicle 10 may further include the thermal paste layer 200 to remove the air layer. The thermal paste layer 200 may be formed by applying a thermal paste between the heating element 300 and the heat sink portion 100. The thermal paste layer 200 may receive heat generated from the heating element 300 and transfer the heat to the heat sink portion 100.

The heat generated from the heating element 300 is radiated to the outside of the control apparatus for vehicle 10 by conduction or convection. Conduction is a mode of thermal conduction in which heat is transferred directly within a material. Heat is transferred as the molecules constituting the material collide with each other or as free electrons within the material move. Convection is a mode of thermal conduction in which heat is transferred as a fluid flows. When a portion of the fluid is heated to create a temperature difference, the fluid flows and transfers the heat.

The heat generated from the heating element 300 is conducted and transferred to the thermal paste layer 200, and the thermal paste layer 200 conducts heat to the heat sink portion 100. The heat sink portion 100 receives the heat and heats the external air of the control apparatus for vehicle 10, and the heat is radiated by convection.

The thermal paste has a liquid phase. The thermal paste formed using a silicone material has a thermal conductivity coefficient of about 0.5 to 3 W/m·K, while thermal paste formed using copper or aluminum has a thermal conductivity coefficient of about 4 to 8 W/m·K.

The air bubbles may be formed inside the thermal paste layer 200, and the heat dissipation effect of the thermal paste layer 200 may be degraded. When the thermal paste layer 200 and the heat sink portion 100 are brought into contact with each other, the thermal paste pushes out the air. If there is insufficient space for the air to escape, the air bubbles may be formed as the air cannot escape.

When turbulence is formed inside the application apparatus, the air bubbles may be formed inside the thermal paste layer 200. The faster the flow rate of the liquid or the higher the viscosity of the liquid, the Reynolds number Re becomes larger, and turbulence may be generated inside the liquid. Accordingly, as the application speed of the thermal paste increases, the air bubbles are formed inside the thermal paste layer 200. Even when a high-viscosity thermal paste is applied, the air bubbles may be formed.

According to an embodiment of the disclosure, after a wrench 20 is engaged with the coupling hole 111, vibration may be applied to remove air bubbles formed inside the thermal paste layer 200. Under conditions of room temperature (about 25° C.) and atmospheric pressure (about 1 atm), the density of the air is 0.001225 g/cm³, while the density of the thermal paste is 2.3 to 3.0 g/cm³. The density of air is significantly lower than the density of the thermal paste. When vibration is applied to the thermal paste layer 200, the air bubbles may rise from the inside the thermal paste toward the upper portion of the thermal paste due to a difference in density.

The thermal paste is a highly viscous fluid. When vibration is applied to the thermal paste, the vibration generates a shear force inside the thermal paste. The shear force increases the flow of the air bubbles in the thermal paste. The air bubbles may easily move toward the surface of the thermal paste layer 200.

As vibration is applied to the thermal paste layer 200, the viscosity of the thermal paste layer 200 decreases locally, so that the air bubbles may easily move. The stronger the bonding force between each of molecules constituting the thermal paste, the higher the viscosity of the thermal paste. When vibration is applied to the thermal paste layer 200, the bonding force between the molecules weakens, and the viscosity of the thermal paste layer 200 locally decreases.

When vibration of a specific frequency is applied toward the thermal paste layer 200, air molecules inside the air bubbles cause resonance, and the air bubbles may collapse and be removed.

The larger the surface area of the heat sink portion 100, the more easily heat may be radiated. The heat sink portion 100 may be formed with a groove formation toward the inside of the control apparatus for vehicle 10 or the accommodation space. When the heat sink portion 100 is formed with a groove formation, it may have a recessed portion (not shown). The recessed portion is formed to be in contact with the thermal paste layer 200.

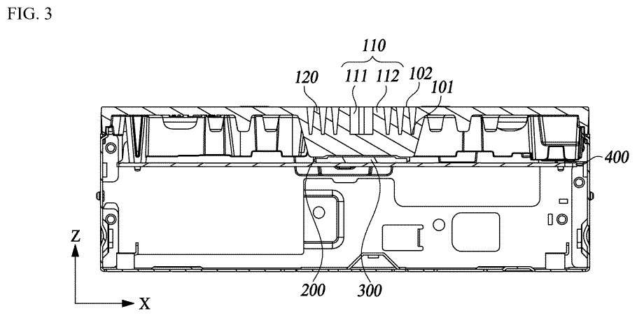

FIG. 3 is a cross-sectional view taken along line A-A′ of FIG. 1.

Referring to FIG. 3, the heat sink portion 100 may further include one or more plates 120 to increase the surface area. The heating element 300 and the heat sink portion 100 are in contact with each other, and heat generated from the heating element is transferred to the heat sink portion 100. The plate 120 is formed to heat the external air of the control apparatus for vehicle 10 and to generate convection. The plate 120 is arranged to increase the surface area of the heat sink portion 100. The plate 120 is formed to have a thin plate shape and may be formed to have a “V” shape or to be bent.

One side of the plate 120 is coupled to at least a portion of the recessed portion to form a heat sink groove 101 and a heat sink ridge 102. The heat sink groove 101 may be a portion to which the plate 120 is not coupled, and the heat sink ridge 102 may be the other side of the plate 120. When the heat sink portion 100 includes a plurality of plates 120, each plate 120 is spaced apart from each other and coupled to the recessed portion. The heat sink groove 101 may be formed between each of the plates 120. Each plate 120 may further include an auxiliary protrusion (not shown) to increase the surface area, and may enhance the heat dissipation effect of the heat sink portion 100.

According to an embodiment of the disclosure, the coupling portion 110 is formed to allow the wrench 20 to engage therewith. The wrench 20 generates vibration and engages with the coupling portion 110 to apply vibration to the heat sink portion 100. The wrench 20 may be a wrench or impact drill that directly generates vibration, such as a vibration wrench. When vibration is generated using a wrench other than the vibration wrench, vibration may be generated by combining the wrench 20 and a vibration device (not shown). The coupling portion 110 may be coupled to at least one of the plates 120.

The coupling portion 110 may include the coupling hole 111 and a coupling bolt 112. The coupling hole 111 is formed with a groove formation that allows the wrench 20 to engage therewith. The coupling bolt 112 is formed to surround the coupling hole 111. The heat sink portion 100 may include the coupling portion 110 to increase the surface area and enhance the heat dissipation effect.

The coupling hole 111 is formed with a groove formation to have any one of a first shape, a second shape, and a third shape. The first shape may be an n-sided shape (n is a natural number of 3 or more), and the second shape may be an n-pointed shape. The n-pointed shape may have n tips or outer vertexes and n valleys or inner vertexes. When the n-pointed shape does not have a vertex or when the protrusion is bent, it may have a torx shape. The first shape is not limited only to a specific polygonal shape, and the second shape is not limited only to a specific pointed shape. A user may remove air bubbles using wrenches 20 having various polygonal shapes or pointed shapes.

When the circumscribed circles of the first shape and the second shape both have the same diameter, the circumference of the second shape is formed longer than the circumference of the first shape. Therefore, when the coupling hole 111 has the second shape, the surface area of the heat sink portion 100 may increase, and the heat sink portion 100 may easily radiate heat.

According to an embodiment of the disclosure, the wrench 20 and the coupling hole 111 each have a third shape and are formed to allow they to engage with each other. The third shape may be a cross-shaped shape, and the third shape includes a center point and first branch to fourth branch. One end of each of the first branch to fourth branch is formed to extend from the center point. The first branch is formed to extend in a first direction and the second branch is formed to extend in a second direction. The first direction may be a direction parallel to the x-axis, and the second direction may be a direction parallel to the y-axis. The second direction may be any direction that intersects the first direction.

When vibration is applied to the heat sink portion to remove air bubbles, the plate 120 may be damaged. When vibration is applied after the heat sink groove 101 and the wrench 20 having different shapes are engaged with each other, the plate 120 may be physically damaged by the vibration. Even when the width of the heat sink groove 101 and the outer diameter of the wrench 20 are different, the plate 120 may be physically damaged.

According to an embodiment of the disclosure, the wrench 20 and the coupling hole 111 have the same shape, and vibration generated from the wrench 20 is transferred toward the heat sink groove 101, allowing vibration to be applied without damaging the plate 120.

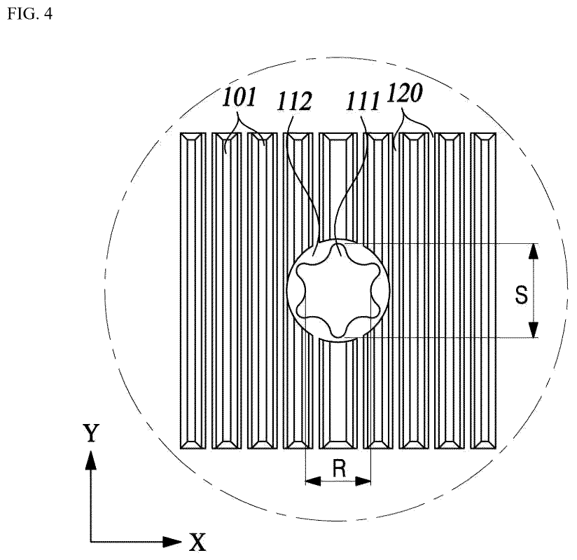

FIG. 4 is a plan view showing a first embodiment of a heat sink portion according to the disclosure.

Referring to FIG. 4, the heat sink portion 100 is formed with a recessed shape. The heat sink portion 100 includes the recessed portion, the coupling portion 110, and the plurality of plates 120, and the coupling portion 110 includes the coupling hole 111 and the coupling bolt 112. The plurality of plates 120 are formed to extend in a first direction or a second direction and are coupled to the recessed portion. Each plate 120 is arranged to be spaced apart from each other to form heat sink grooves 101. At least some of the plurality of plates 120 are coupled to the coupling portion 110. The plurality of plates 120 are arranged to be parallel to each other.

The coupling hole 111 may have the torx shape. The torx shape refers to a hexalobular socket shape specified by ISO 10664. The torx coupling includes a T-torx coupling and an E-torx coupling. The T-torx coupling refers to a torx coupling in which a socket formed on the head of a bolt and a wrench are coupled to each other. The E-torx coupling refers to a torx coupling in which a head of a bolt and a wrench having a shape formed with a recess are coupled to each other.

According to an embodiment of the disclosure, the control apparatus for vehicle 10 is formed to perform T-torx coupling. The wrench 20 has a protruding shape, and the coupling hole 111 is formed with a groove formation to allow the wrench and the coupling hole to engage with each other. A point-to-point distance S (hereinafter referred to as “A value”) refers to a width length between one lobe of the torx shape and another lobe facing the lobe. A tip-to-tip diameter R (hereinafter referred to as a “B value”) refers to a width length between a recess of the torx shape and another recess facing the recess. The wrench 20 and the coupling hole 111 have the same A value and B value. When the value B is divided by the value A, it has a constant value, and may be expressed by Equation 1.

$$\frac{B}{A} \approx 0.72 \qquad [ Equation 1 ]$$

The T-torx has a specification number (hexalobular socket No.) of T1 to T100. The relationship between the specification number, the A value, and the B value of the T-torx is shown in Table 1.

TABLE 1

| | | | |
|---|---|---|---|
| [symbol] | [symbol] | [symbol] | [symbol] |
| [symbol] | [symbol] | [symbol] | [symbol] |
| | | | [symbol] |
| [symbol] | [symbol] | [symbol] | [symbol] |
| [symbol] | [symbol] | [symbol] | [symbol] |
| [symbol] | [symbol] | [symbol] | [symbol] |
| [symbol] | [symbol] | [symbol] | [symbol] |
| [symbol] | [symbol] | [symbol] | [symbol] |
| [symbol] | [symbol] | [symbol] | [symbol] |
| [symbol] | [symbol] | [symbol] | [symbol] |
| [symbol] | [symbol] | [symbol] | [symbol] |
| [symbol] | [symbol] | [symbol] | [symbol] |
| [symbol] | [symbol] | [symbol] | [symbol] |
| [symbol] | [symbol] | [symbol] | [symbol] |
| [symbol] | [symbol] | [symbol] | [symbol] |
| [symbol] | [symbol] | [symbol] | [symbol] |
| [symbol] | [symbol] | [symbol] | [symbol] |
| [symbol] | [symbol] | [symbol] | [symbol] |
| [symbol] | [symbol] | [symbol] | [symbol] |

[symbol]

indicates data missing or illegible when filed

The larger the value A is, the coupling hole 111 and the wrench 20 may be easily engaged with each other, and the wrench 20 may easily apply vibration toward the heat sink portion 100. However, as the A value increases, there is a disadvantage in that the surface area of the heat sink portion 100 decreases and the heat dissipation performance degrades.

According to an embodiment of the disclosure, the coupling hole 111 may be formed to have the first shape or the n-sided shape. The coupling hole 111 and the wrench 20 have the same shape and are formed to be easily engaged with each other.

Even when the coupling hole 111 and the wrench 20 have different shapes, they may be easily engaged with each other if the diameter of the coupling hole 111 is formed to be larger than the diameter of the wrench 20. More specifically, even when the coupling hole 111 has the first shape or the n-sided shape and the wrench 20 has the second shape or the n-pointed shape, engagement may be achieved as long as the diameter of the inscribed circle of the coupling hole 111 is larger than the A value of the wrench 20.

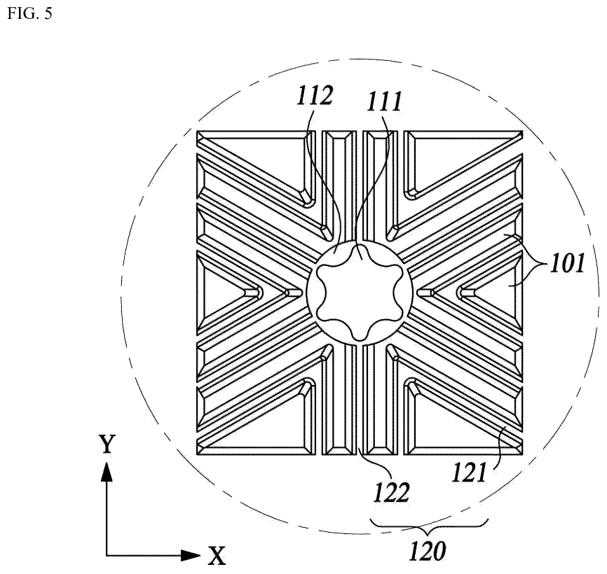

FIG. 5 is a plan view showing a second embodiment of a heat sink portion according to the disclosure.

Referring to FIG. 5, the coupling hole 111 is formed with a groove formation to have the second shape or the n-pointed shape so that the wrench 20 may be engaged therewith. The plate 120 may include a first plate 121 and a second plate 122 to an n-th plate (not shown). One end of each of the first plate to the n-th plate may be coupled to the coupling bolt 112. The first plate to the n-th plate are formed to extend and are arranged to have a radial shape from a center of the coupling portion 110.

When the wrench 20 applies vibration to the heat sink portion 100, the vibration propagates from the coupling hole 111 while maintaining an isotropic state. The wave generated by the vibration propagates uniformly from the coupling hole 111 in all directions. When the first plate to the n-th plate are formed to have the radial shape, each plate 120 is subjected to a uniform force. Even when vibration is applied to the heat sink portion 100, each plate 120 may not be twisted or physically damaged. When the user performs the process of removing air bubbles, vibration may be applied without damaging the plates 120, thereby easily removing the air bubbles formed inside the thermal paste layer 200.

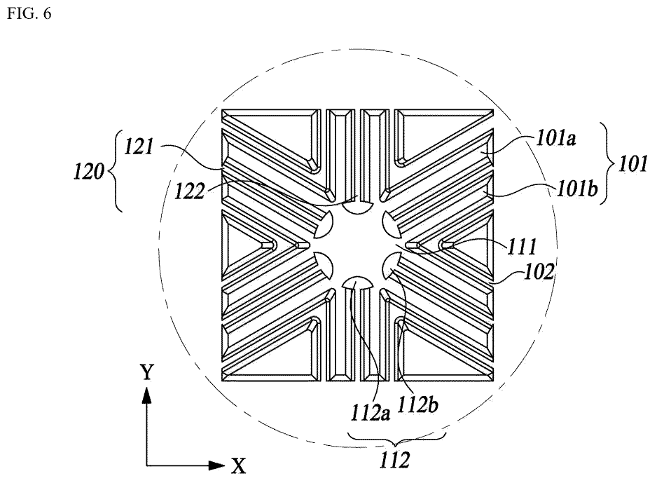

FIG. 6 is a plan view showing a third embodiment of a heat sink portion according to the disclosure.

Referring to FIG. 6, the coupling hole 111 may be formed to be connected to the heat sink groove 101, and the coupling hole 111 and the heat sink groove 101 may be integrally formed. When the coupling hole 111 and the heat sink groove 101 are formed to be coupled, the coupling bolt 112 is formed such that at least a portion thereof is opened. More specifically, the plate 120 includes the first plate 121, the second plate 122 to the n-th plate (not shown), and the coupling bolt 112 includes a first coupling bolt 112a, a second coupling bolt 112b to an n-th coupling bolt (not shown). Each of n-th plate and n-th coupling bolt may be connected or integrally formed. The first plate to the n-th plate are arranged to have the radial shape from a center of the coupling hole 111. The first coupling bolt to the n-th coupling bolt are arranged to be spaced apart from each other such that the coupling hole 111 is formed.

According to an embodiment of the disclosure, the heat sink portion 100 further includes a first heat sink groove 101a, a second heat sink groove 101b to an n-th heat sink groove (not shown). The first plate to the n-th plate are arranged to form the first heat sink groove to the n-th heat sink groove. More specifically, the first plate 121 is formed to extend in the first direction from the center of the coupling hole 111, and the n-th plate is arranged in order so as to have an ascending order along the clockwise direction from the center the coupling hole 111. The first plate 121 and the second plate 122 are arranged to be spaced apart from each other so that the first heat sink groove 101a is formed. The (n−1)-th plate and the n-th plate are arranged so that the (n−1)-th heat sink groove is formed, and the n-th plate and the first plate are arranged so that the n-th heat sink groove is formed.

When at least a portion of the coupling bolt 112 is formed to be opened and the heat sink groove 101 and the coupling hole 111 are connected, the surface area of the heat sink portion 100 may increase. The heat sink portion 100 may easily dissipate heat.

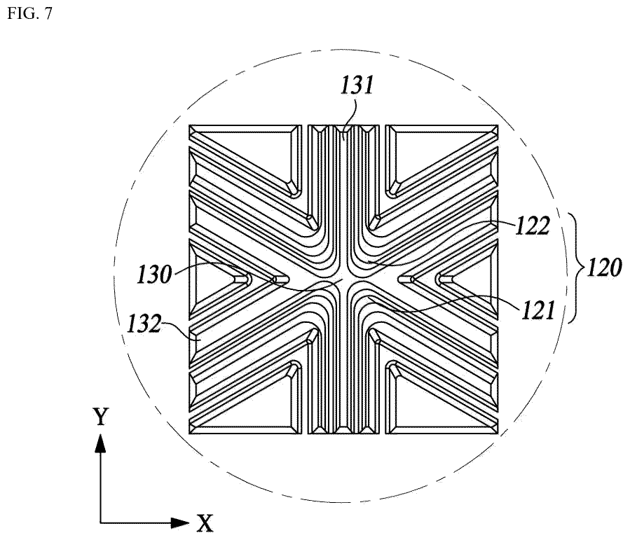

FIG. 7 is a plan view showing a fourth embodiment of a heat sink portion according to the disclosure.

Referring to FIG. 7, the heat sink portion 100 may further include a radiation hole 130. The radiation hole 130 includes a first radiation line 131 and second radiation line 132 to m-th (m is a natural number of 3 or more) radiation line (not shown). The plate 120 further includes the first plate 121, the second plate 122 to an m-th plate (not shown).

The first radiation line to the m-th radiation line are formed to extend radially from a center of the radiation hole 130 and are arranged to be spaced apart from each other so as to form the first plate to the m-th plate. More specifically, the first radiation line 131 is formed to extend in the y-axis direction from the center of the radiation hole 130, and the m-th radiation line is arranged in order so as to have an ascending order along the clockwise direction from the center of the radiation hole 130. The first radiation line 131 and the second radiation line 132 are arranged to be spaced apart from each other, and the first plate 121 is arranged between the first radiation line 131 and the second radiation line 132. An (m−1)-th plate is arranged between the (m−1)-th radiation line and the m-th radiation line, and the m-th plate is arranged between the m-th radiation line and the first radiation line. The first plate to the m-th plate may be formed to be bent or to have the “V” shape. When the first plate to the m-th plate have the “V” shape, the surface area of the heat sink portion 100 may increase, and the heat sink portion 100 may easily radiate heat.

According to an embodiment of the disclosure, the heat sink portion 100 may be formed by arranging only the radiation hole 130 and the plate 120, without including the coupling portion 110. Vibration may be applied by engaging the wrench 20 with the radiation hole 130. When the wrench 20 applies vibration to the heat sink portion 100, the wave generated by the vibration propagates uniformly from the coupling hole 111 in all directions. When the first plate to the m-th plate are formed to have a radial shape, each plate 120 may be subjected to a uniform force. When the process of removing air bubbles is performed, the vibration may be applied without damaging the plates 120, thereby easily removing the air bubbles formed inside the thermal paste layer 200.

The radiation hole 130 includes m radiation lines, the number of radiation lines is not limited. The user may apply vibration using the wrench 20 having an m-pointed shape. The m-pointed shape is not limited to a specific pointed shape. The user may remove air bubbles using the wrench 20 having various m-pointed shapes.

According to an embodiment of the disclosure, the heat sink portion 100 may implement the effects of the disclosure by including only the radiation hole 130 and the plate 120 without including the coupling portion 110.

The embodiment of the disclosure is not limited only to the embodiment of the control apparatus for vehicle 10.

The disclosure may be applied to any control apparatus or container (not shown) that includes the heat sink portion 100, the thermal paste layer 200, the heating element 300, and the printed circuit board 400 and is intended to dissipate heat transferred from the heating element 300.

According to an embodiment of the disclosure, the container includes the heat sink portion 100, the thermal paste layer 200, the heating element 300, the printed circuit board 400, and the housings 500, 600. The heating element 300 is coupled to the printed circuit board 400, and the thermal paste layer 200 is formed on the upper surface of the heating element 300. The heat sink portion 100 is formed on the upper surface of the thermal paste layer 200.

The housings 500, 600 may have an accommodation space formed therein to accommodate the printed circuit board 400, and may further include the upper housing 500 and the lower housing 600. The printed circuit board 400 is accommodated inside the lower housing 600, and the upper housing 500 is formed to be coupled to the lower housing 600 to cover the printed circuit board 400.

The above description is merely illustrative of the technical spirit of the embodiment, and various modifications and variations will be possible to by those of ordinary skill in the art to which the embodiment pertains, without departing from the essential characteristics of the embodiment. Therefore, the embodiments are not intended to limit but to explain the technical spirit of the embodiment, and the scope of the technical spirit of the embodiment is not limited by these embodiments. The scope of protection of the embodiment should be interpreted by the following claims, and all technical spirit within the equivalent scope thereof should be interpreted as being included in the scope of rights of the embodiment.

Description of Signs

10: Control apparatus for vehicle
20: Wrench
100: Heat sink portion
101: Heat sink groove
102: Heat sink ridge
110: Coupling portion
111: Coupling hole
112: Coupling bolt
120: Plate
130: Radiation hole
200: Thermal paste
300: Heating element
400: Printed circuit board
R: Tip-to-tip diameter
S: Point-to-point distance

1. A control apparatus for vehicle comprising:
a lower housing having an accommodation space formed therein configured to accommodate a printed circuit board;
a heating element coupled to the printed circuit board;
a thermal paste layer formed on an upper surface of the heating element; and
an upper housing comprising a heat sink portion disposed on one surface of the upper housing,
wherein the thermal paste layer is formed such that an upper surface thereof is in contact with at least a portion of the heat sink portion,
wherein the heat sink portion comprises:
one or more plates; and
a coupling portion formed such that a wrench engages therewith, and
wherein at least one of the one or more plates has one end coupled to the coupling portion.

2. The control apparatus for vehicle of claim 1, wherein
the heat sink portion is formed with a groove formation toward the accommodation space.

3. The control apparatus for vehicle of claim 2, wherein
the one or more plates are arranged to be spaced apart from each other so as to form one or more heat sink grooves, respectively.

4. The control apparatus for vehicle of claim 1, wherein
the wrench is formed to have a cross-shaped shape, and
the coupling portion comprises a coupling hole with a groove formation configured to allow the wrench to engage therewith, the coupling hole being formed to have a cross-shaped shape, and a cross-shaped shape includes a center point and first branch to fourth branch and one end of each of the first branch to fourth branch is formed to extend from the center point.

5. The control apparatus for vehicle of claim 1, wherein
the one or more plates comprise a first plate to an n-th plate, wherein an n is a natural number of 3 or more,
the coupling portion comprises a coupling hole with a groove formation configured to allow a wrench to engage therewith, the coupling hole having an n-pointed shape, and
an end of each of the first plate to the n-th plate of the one or more plates is coupled to the coupling portion, wherein the first plate to the n-th plate of the one or more plates is configured to be formed to extend radially from a center of the coupling portion.

6. The control apparatus for vehicle of claim 5, wherein
the heat sink portion further comprises a first heat sink groove to an n-th heat sink groove, and
the first plate to the n-th plate are of the one or more plates arranged to be spaced apart to form the first heat sink groove to the n-th heat sink groove, the coupling hole further comprising a coupling bolt formed to surround the first heat sink groove to the n-th heat sink groove and the coupling hole.

7. The control apparatus for vehicle of claim 5, wherein
the coupling hole is formed with a groove formation to have an n-sided shape.

8. The control apparatus for vehicle of claim 1, wherein
the heat sink portion further comprises a radiation hole with a groove formation configured to allow a wrench to engage therewith, the radiation hole including a first radiation line to an m-th radiation line, wherein an m is a natural number of 2 or more,
wherein the first radiation line to the m-th radiation line of the radiation hole are configured to be formed to extend radially from a center of the radiation hole and are arranged to be spaced apart from each other so as to form a first plate to an m-th plate of the one or more plates.

9. A container comprising:
a lower housing having an accommodation space formed therein configured to accommodate a printed circuit board;
a heating element coupled to the printed circuit board;
a thermal paste layer formed on an upper surface of the heating element; and
an upper housing comprising a heat sink portion disposed on one surface of the upper housing,
wherein the thermal paste layer is formed such that an upper surface thereof contacts at least a portion of the heat sink portion,
wherein the heat sink portion comprises:
one or more plates; and
a coupling portion formed such that the wrench engages therewith, and
wherein at least one of the one or more plates is formed such that one end thereof is coupled to the coupling portion.

10. The container of claim 9, wherein
the heat sink portion further comprises a radiation hole with a groove formation that allows a wrench to engage therewith, the radiation hole comprising a first radiation line to an m-th radiation line, wherein an m is a natural number of 2 or more,
wherein the first radiation line to the m-th radiation line of the radiation hole are configured to be formed to extend radially from a center of the radiation hole and arranged to be spaced apart from each other so as to form a first plate to an m-th plate of the one or more plates.
